(19) United States
(12) Patent Application Publication
(10) Pub. No.: US 2022/0152746 A1
(43) Pub. Date: May 19, 2022

(54) RECLAMATION AND RECYCLING OF SEMICONDUCTOR WORKPIECES

(71) Applicant: ABM CONSULTING, L.L.C., Buchanan Dam, TX (US)

(72) Inventors: Andrew Beers, Cottonwood Shores, TX (US); Ronald Macklin, Austin, TX (US)

(21) Appl. No.: 17/591,709

(22) Filed: Feb. 3, 2022

Related U.S. Application Data
(63) Continuation of application No. PCT/US2020/046558, filed on Aug. 14, 2020.
(60) Provisional application No. 62/887,151, filed on Aug. 15, 2019.

(51) Int. Cl. B23K 26/40; B23K 26/12; B23K 26/06; H01L 21/67

(52) U.S. Cl. CPC B23K 26/40; H01L 21/67115; B23K 26/0643; B23K 26/127

(57) ABSTRACT

Reclamation or recycling of a semiconductor workpiece includes vaporizing the structures and materials deposited, implanted, or formed in or on the substrate with minimally acceptable damage to the crystalline substrate through direct ionic vaporization rather than thermal ablation. The purity of the substrate therefore remains substantially free from heavy metal surface contamination and has a surface roughness that may be polished back to a mirror-like finish using chemical mechanical polishing or lapping processes. The process includes focusing coherent light on a surface of the substrate with a predetermined wavelength, power, pulse width, and pulse rate or number of pulses per unit area that causes direct ionic vaporization of material formed in or on the surface of the substrate up to a predetermined penetration depth. Advantageously, patterned, previously used test, and out of specification wafers may be reclaimed for reuse or recycled without risk of the unintended disclosure of intellectual property.

### CROSS-REFERENCE TO RELATED APPLICATIONS

This application is a continuation of PCT International Application Serial Number PCT/US2020/046558, filed on Aug. 14, 2020, which claims the benefit of, or priority to, U.S. Provisional Patent Application Ser. No. 62/887,151, filed on Aug. 15, 2019, both of which are hereby incorporated by reference in their entirety for all purposes.

### TECHNICAL FIELD OF THE INVENTION

The present invention relates to methods of, and systems for, the removal of multi-level patterned metals, dielectrics, and semiconducting materials from a semiconductor or dielectric substrate to prevent the disclosure of intellectual property and enable the reclamation or recycling of the semiconductor workpiece.

### BACKGROUND OF THE INVENTION

Semiconductor fabrication refers to the complex processes used to manufacture modern integrated circuits. While numerous, the process steps may be grouped into four general categories: 1) starting-material processes that produce polished semiconductor wafer substrates, 2) patterning processes that guide the deposition or removal of material from the wafer substrates, 3) deposition or growth processes that dispose semiconducting materials on the wafer substrates, and 4) etching, chemical mechanical polishing, or masking processes that selectively remove material from, or add material to, the wafer substrates.

FIG. 1 shows a conventional process 100 for the manufacture of a semiconductor wafer substrate for use in semiconductor fabrication. A semiconductor wafer is a thin semiconducting material that is used as a substrate for devices to be built in and upon the substrate during the fabrication process. Semiconductor wafers are specified by their diameter, typically in a range between 25.4 mm and 450 mm, with 200 mm and 300 mm being the most common diameters in use today. The diameter of the wafer determines, in part, the number of semiconductor devices that may be fabricated on a given wafer. The starting material for the manufacture of a semiconductor wafer is typically single-crystal silicon, but gallium arsenide, silicon carbide, quartz, sapphire, germanium, or other periodic table group III-V semiconductors may be used. For purposes of illustration, using silicon as the most common substrate material, the wafer fabrication process starts with the purification of raw silica to remove impurities, resulting in a polycrystalline silicon material. The Czochralski method 105 is the most common method used to grow a single-crystal ingot by placing a single-crystal seed of a certain crystalline orientation on one end of a shaft and rotating it slowly through and away from molten polycrystalline silicon. The melting and refreezing of the silicon at the seed interface allows crystal formation following the crystal structure of the seed. The conversion of molten polysilicon into monocrystalline silicon continues as the seed is slowly withdrawn from the melt. After crystal growth, the resulting silicon ingot is cropped, notched, and ground 110 to produce a flat or notch that parallels the crystal growth orientation axis. The ingot is then sliced 115 with a diamond wire saw into discrete wafers having a thickness in a range between 500 microns and 1000 microns, which is wafer dependent, with 750-775 microns commonly used for 300 mm wafers. Silicon in its crystalline state is brittle and the edge must be profiled or rounded off 120 to prevent flaking or other failure modes during subsequent processing steps. The sliced wafers are then laser marked 125 on either the front or backside so that the wafer and fabrication process may be traced during processing. The wafers are then lapped 130 to remove any damage or irregularities caused by slicing. The wafers are then chemically etched 135, polished 140, and cleaned 145 to produce a mirror-like surface of optical quality and defectivity. During epitaxial deposition 150, epitaxial films or layers may be deposited or grown on the crystalline substrate. The wafers are then inspected 155 to ensure that they meet numerous electrical, chemical, mechanical, and surface specifications. The finished wafers that meet specifications are placed in a wafer cassette 160 for delivery to a semiconductor fabrication plant, commonly referred to as a fab and sometimes referred to as a foundry, for use in the semiconductor fabrication process.

For purposes of illustration only, FIG. 2 shows a conventional process 200 for semiconductor fabrication using semiconductor wafers. The fabrication process is typically partitioned into what is commonly referred to as front-end-of-line, back-end-of-line, and back-end packaging processes. The front-end-of-line includes the processes that form isolated p-type (or boron doped) or n-type (or phosphorus doped) metal-oxide-semiconductors (“MOS”) or complementary-MOS (“CMOS”) structures in and on the substrate. The back-end-of-line includes the processes that form internal metal interconnects between structures and devices. Back-end packaging includes various post-fab processes including wafer test, wafer back grinding, die singulation, integrated circuit packaging, and final test. During front-end-of-line processes, a thin layer of silicon nitride, silicon dioxide, and photoresist may be applied 205 to the surface of a polished semiconductor wafer. During patterning and photolithography 210, light may be focused through a reticle or mask to project patterns onto the semiconductor wafer. The exposed photoresist after developing is then removed 215 and the exposed areas are feature etched 220. During ion implantation 225, ions are showered onto the etched or patterned areas to selectively dope, or modify, conductivity on the wafer substrate as necessary for device fabrication. Additional photoresist may be spun onto the wafer and the patterning 210, photoresist removal 215, etching 220, and chemical mechanical processing steps may be repeated as needed to form the desired structures. During back-end-of-line processes, a similar process (not shown) may be used to apply a plurality of metal layers 230 that form the metal interconnects between the structures and devices. During back-end packaging, the wafer may be diced, separating out individual integrated circuits, that are then bumped or balled (not shown) for use in electronic devices.

### BRIEF SUMMARY OF THE INVENTION

According to one aspect of one or more embodiments of the present invention, a method of reclamation or recycling of a semiconductor workpiece includes focusing coherent light on a surface of a semiconductor substrate. The coherent light has a predetermined wavelength, power, pulse width, and pulse rate or number of pulses per unit area that causes direct ionic vaporization of material formed in or on the surface of the substrate up to a predetermined penetration depth. The method further includes purging the surface of the substrate with a purge gas and exhausting the surface of the substrate.

According to one aspect of one or more embodiments of the present invention, a system for reclamation or recycling of a semiconductor workpiece includes a coherent light source that generates a coherent light having a predetermined wavelength, power, pulse width, pulse rate or number of pulses per unit area that causes direct ionic vaporization of material formed on or in the surface a semiconductor substrate up to a predetermined penetration depth, a lens or mirror that focuses the coherent light on the surface of the substrate, a gas purging system that purges the surface of the substrate, and an exhaust system that exhausts the substrate.

Other aspects of the present invention will be apparent from the following description and claims.

### BRIEF DESCRIPTION OF THE DRAWINGS

FIG. 1 shows a conventional process for the manufacture of a semiconductor wafer substrate.

FIG. 2 shows a conventional process for semiconductor fabrication using semiconductor wafers.

FIG. 3 shows a cross-section of a portion of an exemplary integrated circuit on a fabricated semiconductor wafer substrate.

FIG. 4 shows exemplary specifications for a commercially available neodymium-doped yttrium aluminum garnet 3^{rd} harmonics laser.

FIG. 5 shows exemplary specifications for a commercially available titanium-sapphire laser.

FIG. 6 shows exemplary specifications for a commercially available carbon dioxide laser.

FIG. 7 shows the desired zone of clean ablation without redeposition of material or melting.

FIG. 8 shows a 780 nm circular spot Ti-sapphire laser achieving the ablation threshold fluence in silicon.

FIG. 9 shows laser pulse parameters that are dependent on the material properties of the target substrate to be ablated.

FIG. 10 shows a two-temperature model thermo-optical model of laser ablation in relation to a wafer substrate in accordance with one or more embodiments of the present invention.

FIG. 11A shows the depth of a point of optical penetration of a laser impinging on a surface of the wafer substrate in accordance with one or more embodiments of the present invention.

FIG. 11B shows the depth of a point of thermal penetration of a laser impinging on a surface of the wafer substrate in accordance with one or more embodiments of the present invention.

FIG. 11C shows the depth of a point of combined optical and thermal penetration of a picosecond laser on a wafer substrate in accordance with one or more embodiments of the present invention.

FIG. 12A shows a two-temperature model thermo-optical model of a femtosecond pulsed laser into a wafer substrate in accordance with one or more embodiments of the present invention.

FIG. 12B shows the mathematical result of a femtosecond laser pulse into a wafer substrate in accordance with one or more embodiments of the present invention.

FIG. 12C shows the final clean ablation result using a femtosecond laser pulse in accordance with one or more embodiments of the present invention.

FIG. 13 shows a circular or ellipsoidal (spot) laser impinging on a wafer substrate in accordance with one or more embodiments of the present invention.

FIG. 14 shows a line-based laser impinging on a wafer substrate in accordance with one or more embodiments of the present invention.

FIG. 15 shows a cross section of a system for reclamation or recycling of a semiconductor workpiece in accordance with one or more embodiments of the present invention.

FIG. 16A shows a top-facing perspective view of a patterned wafer substrate prior to ablation in accordance with one or more embodiments of the present invention.

FIG. 16B shows a top-facing perspective view of a post-processed wafer substrate after ablation in accordance with one or more embodiments of the present invention.

FIG. 17A shows a top plan perspective exemplary microscopic view of three-dimensional features of a patterned substrate in accordance with one or more embodiments of the present invention.

FIG. 17B shows a top plan perspective exemplary atomic force microscopy view of the wafer surface after ablation in accordance with one or more embodiments of the present invention.

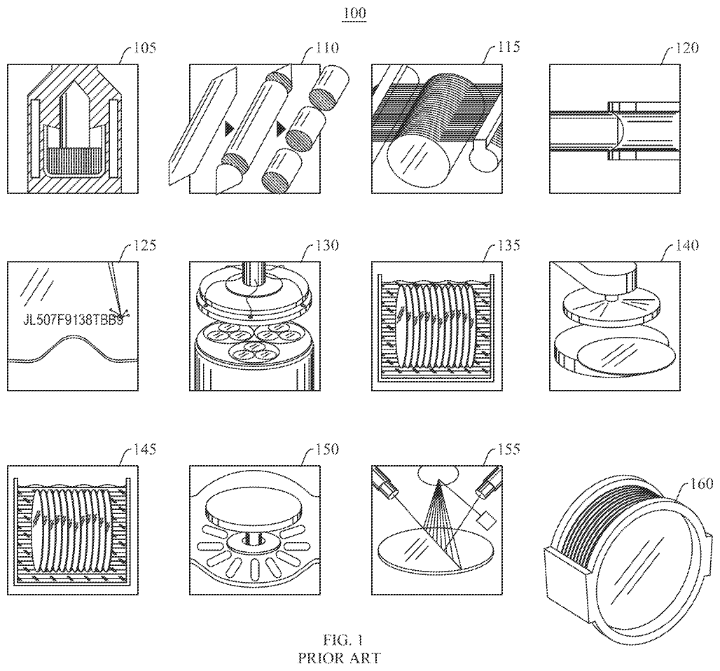

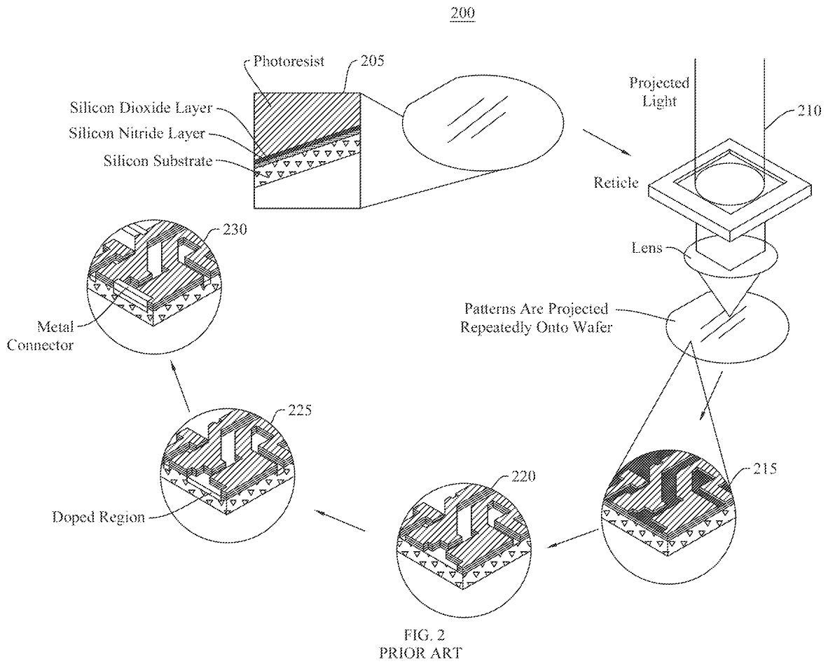

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth to provide a thorough understanding of the present invention. In other instances, well-known features to those of ordinary skill in the art are not described to avoid obscuring the description of the present invention.

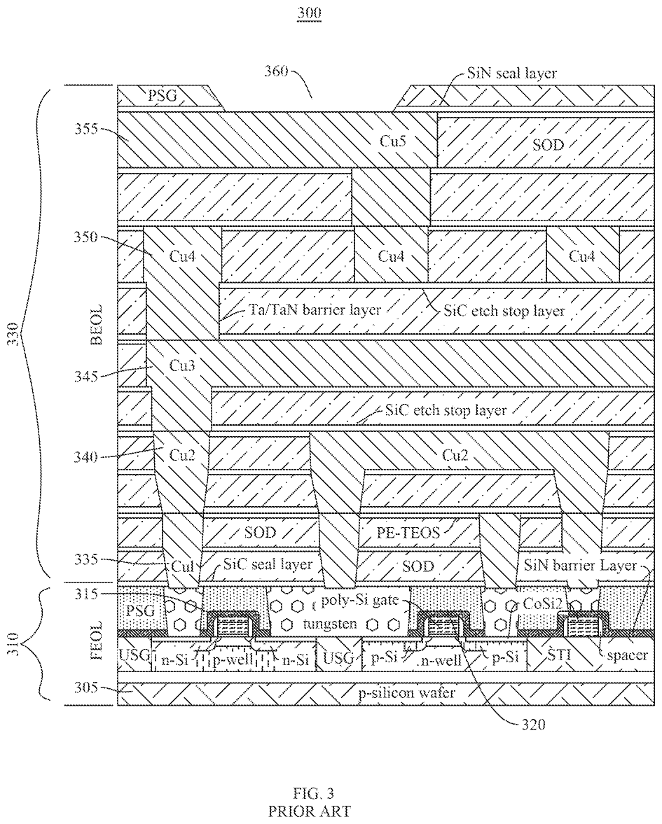

FIG. 3 shows a cross-section 300 of a portion of an exemplary integrated circuit on a fabricated semiconductor wafer substrate, sometimes referred to as a semiconductor finished good. As discussed above, the semiconductor fabrication process results in a fabricated semiconductor wafer having, in cross-section, a front-end-of-line (“FEOL”) portion 310 disposed partially within the substrate 305 and partially above the substrate 305, a back-end-of-line (“BEOL”) portion 330 disposed above the FEOL and the substrate, and a back-end packaging portion (not shown) disposed above the BEOL 330, the FEOL 310, and the substrate 305. In this way, the substrate 305 forms the base upon which the various structures are constructed. The substrate 305 is typically 750-775 microns thick for 300 mm wafers in common use and is either rough polished to less than 100-micron surface roughness, Rₐ, or fine polished to a mirror-like finish having less than 2-micron surface roughness, Rₐ, on both the backside and the frontside. Structures and devices are then built up, layer by layer, from the thinnest layers or gates at the base frontside surface to form the transistors, resistors, and capacitors that are the fundamental devices used to make an integrated circuit.

The FEOL portion 310 may include everything from the structures or devices (e.g., n-p-n MOS transistors 315 or p-n-p MOS transistors 320) formed in or on the substrate 305 up to, but not including, the metal interconnect layers (e.g., metal layers 335, 340, 345, 350, and 355). The structures or devices that comprise the FEOL 310 (e.g., n-p-n MOS transistors 315 or p-n-p MOS transistors 320) are typically very thin and narrow, especially the gates, switches, and surrounding dielectrics, but may include structures as large as tens of microns on a side. While the thickness may vary from application to application, the FEOL 310 typically has a thickness in a range between 5 and 10 microns inside the substrate for ion implantation and substrate doping electrical properties modification and shallow trench electrical isolation and between 1 and microns on the surface through the gate/switch portions. The BEOL portion 330 may include a plurality of metal interconnect layers such as, for example, metal layer 335, metal layer 340, metal layer 345, metal layer 350, and metal layer 355 that serve as the metal interconnects for the structures or devices. While the number of metal interconnect layers, and the thickness of the BEOL 330, may vary from application to application, the BEOL 330 typically has a thickness in a range between 1 and 100 microns for BEOL interconnect portion. A plurality of pads of exposed metal 360, one of which is partially shown, are disposed above the BEOL 330 to bump or ball the device during packaging. The pads 360 are typically 40 microns by 40 microns in size and between 1 and 2 microns in thickness for pads and up to 10 microns for the top surface electrical isolation dielectrics (not shown). Taken together, the thickness of the built-up structures, excluding any contributions from back-end packaging, is represented by the thickness of the FEOL through the BEOL, including those portions of the FEOL that extend into the substrate. As such, the built-up thickness of a fabricated semiconductor wafer may be in a range between 2 and 20 and may extend up to 10 microns below the nominal surface of the substrate.

In addition to the above, it is important to note that some finished semiconductor goods include more complicated designs that introduce additional complexity to the anatomy of the built-up portions of the substrate. For example, some devices may include thin film transistors composed of thin semiconducting films that are less than one micron thick inside BEOL structures. Advanced memory devices may include 128 patterned levels built like stair steps above the substrate. In addition, a complex of metals may be used as interfaces to the conducting metals or as diffusion barriers. Such metals may include titanium nitride, tantalum nitride, tungsten, tungsten silicide, ruthenium, cobalt, or cobalt silicide or other intermetallic combinations of rare Earth elements (“REE”). Moreover, the dielectrics are typically nitrides and oxides of silicon, including, silicon nitride, and silicon dioxide, and many of the oxides are doped with phosphorus, boron, arsenic, carbon, germanium, or oxygen in the case of dopants used under the gate levels inside the wafer substrate. Many of these elements have very high vaporization and/or melting points and are very difficult to remove from the substrate, even using diamond grit tools such as grinding wheels or polishing disks or pads, in comparison to the relatively low vaporization/melting points of copper and aluminum found in the bulk of the metallization layers. As such, a finished semiconductor good, includes a semiconductor wafer that has been patterned, etched, chemically mechanically polished and built upon to form the complex interconnect of structures and devices composed of a variety of elements that form the integrated circuit that adds complexity to their removal.

As previously discussed, semiconductor wafers are substrates composed of single-crystal silicon, gallium arsenide, silicon carbide, quartz, sapphire, germanium, or other periodic table group III-V semiconductors. Several layers of thin films, typically made of aluminum, copper, or gold are patterned above, and electrically connected to, aluminum, polysilicon, tungsten, titanium, ruthenium, or cobalt interconnects for gates or switches. These interconnects use complex thin diffusion barrier liner films which form ohmic electrical contacts typically made of titanium, titanium nitride, tungsten, copper, or aluminum that form transistors that serve as logic, memory, or vertically integrated capacitors in complex integrated circuits. This includes, but is not limited to, microprocessors, microcontrollers, dynamic random access memory (“DRAM”), static random access memory (“SRAM”), magnetic random access memory (“MRAM”), non-volatile random access memory (“NVRAM”) electronically programmable read only memory (“EPROM”), electronically erasable programmable read only memory (“EEPROM”), thyristors, power transistors, and sensors such as charge coupled devices (“CCDs”) used in cameras. Fabricated structures in such devices are known to contain thousands or millions of patterned features that may vary from a few angstroms to several microns thick and may be as small as single digit nanometers in width. Each integrated circuit may include billions of such structures laid out across the substrate and there may be several hundred or more integrated circuits per fabricated semiconductor wafer or substrate.

Semiconductor wafers are typically graded based on a number of complex specifications and acceptance criteria that are beyond the scope of this discussion. Notwithstanding, prime production wafers are considered the highest grade of wafer and typically refer to those wafers that meet or exceed all specifications and acceptance criteria. Prime production wafers are considered the preferred wafer for the commercial production of integrated circuits. Because of the complexity and the substantial expense involved in the semiconductor fabrication process, fabs and foundries, are constantly evaluating their processes in an effort to control them, often using what are commonly referred to as test wafers. Prime test wafers are considered a grade lower than prime production wafers and typically refer to those wafers that fail one or more specifications or acceptance criteria, precluding their use in the commercial production of integrated circuits. For example, test wafers do not have, nor meet, a flatness or defectivity specification and there are typically few backside specifications except for polish or chemically etched and general defectivity and flatness specification. While test wafers may not be production worthy, they still play an important role in the semiconductor fabrication process as they are used by the fab or foundry to test, qualify, and control the various processes involved. Within the category of test wafers, the highest grade of test wafer is referred as a prime test wafer. A prime test wafer typically refers to a test wafer that is of the highest quality and largely suitable for production use but is relegated to use as a test wafer for failing to meet at least one, but typically few, specification or acceptance criteria. While rarely used due to cost, prime test wafers may be used when the quality of the wafer is relevant to the evaluation of the process being controlled. A somewhat more relaxed definition of a prime test wafer, commonly used in the industry, is a test wafer that fails to meet the defectivity or electrical resistivity property requirements for production use, but is substantially clean, flat, polished, and possesses highly controlled round edges.

Since the invention of the integrated circuit, fabs or foundries have used these less expensive test wafers to screen materials and evaluate equipment to test, qualify, and control various fabrication processes. Therefore, in essence, test wafers may be thought of as non-yielding production semiconductor wafers that are put through at least part of the fabrication process in order to evaluate and ultimately control various processes for precision and predictability and to optimize finished die yield and functionality. For example, fabs and foundries use test wafers to measure, optimize, qualify, and control processes for the deposition of films (e.g., growth rate, stress, uniformity, thickness, and defectivity), doping of the substrate with diffusion or ion implantation, plasma etching, chemical mechanical polishing, and lithographic patterning of various layers for surface particle defect control, and process controls for the removal of films during the process to form interconnects and to keep the wafers flat and planar or even to condition process equipment internal environments prior to the commitment of production wafers to that particular process.

Recent reports from the five largest fabs and foundries in the world, report capacity to process a total in excess of 10 million 200 mm wafer equivalents per month and they represent slightly more than fifty percent of the total global capacity. Meaning the total global capacity is nearly 20 million 200 mm wafer equivalents per month or 240 million 200 mm wafer equivalents per year. Even if a conservative estimate of wafer starts is used to estimate the actual number of wafers processed, at least several million wafers are processed each and every year. It is estimated that approximately 10 to 20 percent of the substrates used in the semiconductor fabrication process are used exclusively as test wafers to evaluate individual processes for qualification and control purposes. As such, the semiconductor industry at large is producing a significant number, likely at least hundreds of thousands and perhaps even millions, of test wafers each year, at substantial expense. Some large fabs or foundries reportedly spend upwards of 2 million dollars per month on test wafers alone. In addition to test wafers, many wafers that are processed and patterned, intended for production use, do not meet specifications or compliance criteria at some point during the process. Since these wafers cannot be used for production, the fabs or foundries cut their losses and do not send them out for dicing and packaging. Thus, the semiconductor industry requires a significant number of test wafers and produces an equally significant number of processed test wafers and non-spec wafers, collectively referred to as failed wafers, each year at considerable expense. In addition, the constant need for test wafers burdens the supply chain that sometimes cannot meet demand and fabs and foundries must resort to using expensive prime wafers, intended for production, for testing, qualification, and control purposes.

In view of these issues, foundries have looked to both internal and external processes to mitigate the exorbitant costs associated with failed wafers. Generally speaking, reclamation refers to processes that have, as a goal, the refinishing of a semiconductor wafer, that is not suitable for production use, to at least a quality sufficient for use as a test wafer used in the BEOL. Conventional reclamation processes include stripping the wafer with harsh acid chemicals, polishing and cleaning the wafer by lapping, and then performing chemical mechanical polishing that thins the substrate. As such, reclamation wafers are thinner than production wafers and are only suitable for use as test wafers, and are only suitable for use as test wafers while minimum specified thickness is met. In addition, the reclamation process is labor intensive, time consuming, expensive to perform, and is not environmentally friendly due to the harsh acids and chemicals required. Recycling can be distinguished from reclamation in that, recycling generally refers to processes that have, as a goal, the repurposing of a semiconductor wafer such that it is no longer used as a test wafer or has been damaged, chipped, or otherwise broken.

It is important to note that, to date after internal fab or foundry test wafer recycling processes are exhausted, conventional reclamation and recycling processes are typically performed outside the fab or foundry for a variety of reasons. Fabs and foundries send their failed wafers out for reclamation and eventual reuse as test wafers or they send patterned production wafers or patterned test wafers out for recycling. Notwithstanding, this is potentially problematic for fabs and foundries and their clients that do not want to disclose the intellectual property that is represented by the failed wafers to others, especially their competitors. The concern is that the fabricated wafers, in the hands of a skilled competitor, could be de-processed and the intellectual property contained thereon could be reverse engineered to understand the manufacturing process or even the layout or functionality of the design. Faced with limited options for proceeding, fabs and foundries must decide whether they send their failed wafers out for reclamation or recycling, and if so, how to protect their, as well as their client's, intellectual property. In light of these circumstances, some foundries have internal reclamation or recycling programs in place. With respect to reclamation, some foundries will simply reuse test wafers, in as-is condition, in a different part of the fab. For example, a test wafer used in the early part of the fabrication process must remain uncontaminated by certain dopants and metals which can diffuse or contaminate the electrical properties of the semiconductor. Copper, for example, is the most feared contaminant to bare semiconductor wafers and FEOL semiconductor equipment. After exposure, the test wafer may only be of service to control other processes in other parts of the fab. Similarly, a test wafer exposed to rare earth metals must remain in the BEOL to prevent potential heavy metal contamination of the bare substrate. Very stringent specifications for heavy metal contamination exist not only for new wafers, but for externally reclaimed test wafers as well. While these internal reclamation programs may extend the usable life of a test wafer, they are somewhat limited in their ability to do so. Once a test wafer has come to the end of its usable life for various reasons, fabs and foundries will typically recycle the wafer to the solar industry for production of ingots used to manufacture new solar wafers. Again, fabs and foundries have internal programs to recycle test wafers, but any failed patterned production wafer or failed patterned test wafer must be sent out, once again giving rise to the potential disclosure of their or their client's intellectual property.

Recycling programs typically repurpose a semiconductor wafer, often for use in the manufacture of other products. Sometimes the wafer fab, foundry, or the client, but usually a third-party broker or scrapper, strip the wafers using harsh chemicals such as hydrofluoric or nitric acid, dry plasma stripping, or grinding and polishing and then shatter the base silicon, typically for use in new melts and ingots used to manufacture solar wafers. These processes are usually performed by scrappers overseas because they generate copious amounts of hazardous waste and often expose both the scrapper as well as the environment to harsh chemicals that would violate Occupational Health and Safety Administration (“OSHA”) regulations in the United States. It is important to note that, prior to the conception of the claimed invention, the semiconductor industry lacked the ability to safely and cost effectively reclaim or recycle fabricated substrates in a green manner that protects the fab, foundry, or their client's, intellectual property.

In view of the above, there are several factors that motivate the recovery and reuse of previously scrapped wafers as test wafers: 1) there are a significant number of failed wafers, including test wafers and non-spec wafers, that are candidates for safe and effective reclamation or recycling processes, 2) some of these wafers, specifically the out of specification wafers, are high quality wafers that started life as prime wafers that are excellent candidates for use as test wafers, 3) during high demand periods, test wafers are in short supply, often requiring foundries to use prime production wafers in lieu of prime test wafers, 4) rare earth elements are also in short supply and prices continue to rise as more exotic metals and elements are used throughout the global electronics supply chain, a problem exacerbated by the fact that China controls access to many of these materials, 5) fabs or foundries that reclaim or recycle wafers often use overseas scrappers that use processes that produce copious amounts of hazardous waste that poses a significant risk to the health and safety of scrappers and the environment, often in countries that do not take sufficient steps to protect either, and 6) fabs, foundries, and their client's, are not willing to take on any risk of the inadvertent disclosure of their intellectual property to competitors. For these reasons and others, advanced leading-edge foundries simply destroy failed wafers, or store them for extended periods of time, rather than risk any loss of intellectual property. Thus, there is a long felt, but unsolved need in the industry to provide a safe and effective method of reclamation and recycling of failed wafers that protects the intellectual property of the fab, foundry, and their clients.

Accordingly, in one or more embodiments of the present invention, a method of, and system for, reclamation or recycling of semiconductor workpieces enables the reuse or recycling of substantially full-thickness patterned wafers by way of a safe, non-hazardous, and green process for the complete removal of patterns and materials from the substrate in a manner that leaves the base substrate of sufficient thickness and purity so that it may be polished back to a mirror-like finish and reused as a test wafer or safely sold off as a carrier wafer, scrapped, or recycled for use in the solar industry, without risk of the unintended disclosure of intellectual property. Advantageously, failed wafers, including both test wafers as well as out of specification wafers may be reclaimed for use as test wafers, meeting not only the outsize demand for test wafers, but also driving down semiconductor fabrication costs. In addition, any intellectual property on the failed wafers may be fully removed, thereby allowing even those organizations with the strictest of controls to participate in a reclamation or recycling program that drives down costs. For the first time, the semiconductor industry has a process to reclaim or recycle patterned wafers in a safe, effective, and green manner with a high degree of confidence that intellectual property is fully removed from the substrate.

In one or more embodiments of the present invention, an impinging collimated laser or collimated beam of light (low-frequency wavelength), either in the form of a spot or line, may be directed onto a wafer at atmosphere, or through a suitable transparent transmissive window at reduced atmospheric conditions in a vacuum. The wafer or light source may be mechanically rastered, scanned via galvanometry, or scanned mechanically across the entire surface of the wafer to selectively and completely remove the structures and materials deposited, implanted, or formed in or on the substrate with minimally acceptable damage to the crystalline substrate through ionic vaporization rather than thermal ablation. The purity of the substrate therefore remains free from heavy metal surface contamination and has a sufficient surface roughness that may be polished back to a mirror-like finish using well-known chemical mechanical polishing or lapping processes. The focal point of the light source is focused on the reflective surface of the substrate below the device layers by adjusting the light source focal point in the vertical z-axis either by adjusting the last mirror position of the light source, adjusting the light source height, or by adjusting the substrate height in the z-axis with a vertically moveable and adjustable stage. The stage and/or the laser spot or line may be moved such that the light source spot or line moves across the substrate in the horizontal x- and y-, or rotational r-theta axis movement of the stage or light source.

To directly ionically and instantaneously vaporize the structures formed in and on a failed wafer, consideration of the different types or kinds of metals, inter-metallics, dielectrics as well as their vaporization energies, must be considered. Conventional failed wafers may include semiconducting metals, dielectrics, pure metals, and intermetallic composite metals. Additionally, consideration must be given to the types or kinds of lasers and the energy levels required to complete vaporization without substantial substrate crystalline damage or heavy metal contamination by diffusion. While there are three ablation mechanisms, namely, melting, milling, and ionization, to achieve ionic ablation without significant damage to the substrate requires quickly reaching the ionization-vaporization threshold, because melting and milling result in unacceptable slag of material being redeposited on the substrate surface creating too much material to be removed by polishing and the diffusion of impurities too deep into the substrate, contaminating it beyond useful recovery. Substrates are nominally recoverable only in repeated cycles down to a useful thickness in the −640-680 micron range. Beyond that point, 200 mm and 300 mm substrates are typically scrapped for recycling use in the manufacture of solar cells. In certain embodiments, coherent light laser sources from ultraviolet (“UV”) wavelengths (e.g., approximately 157 nm to 380 nm), visible wavelengths (e.g., approximately 380 nm to 750 nm), and near infrared wavelengths (e.g., approximately 808 nm to 2000 nm) may be used, so long as the spot size, typically 1 to 5 micron in diameter in the case of a spot, or in width in the case of a line, reaches and maintains the ablation/vaporization material threshold of approximately 0.2 Joules/cm² and above, up to approximately 2.5 J/cm² (substrate material dependent).

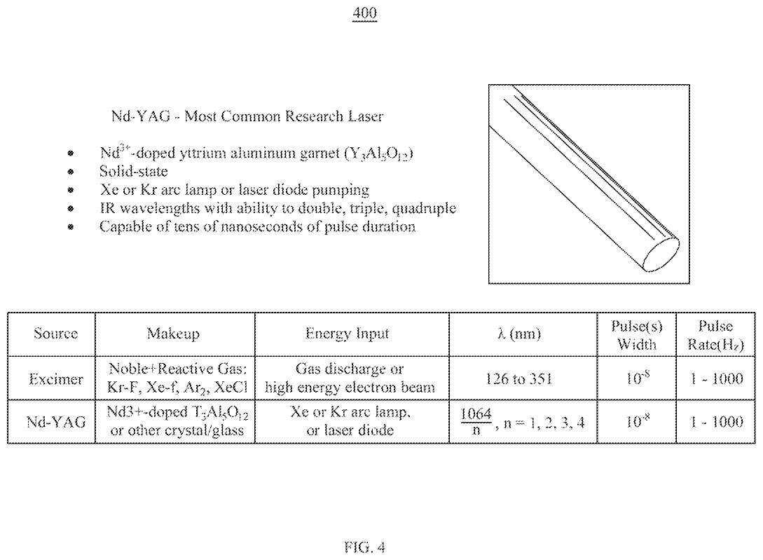

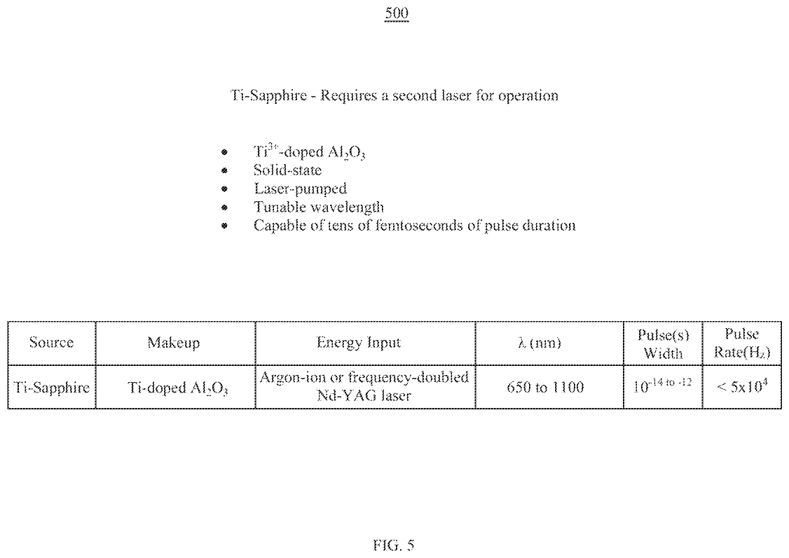

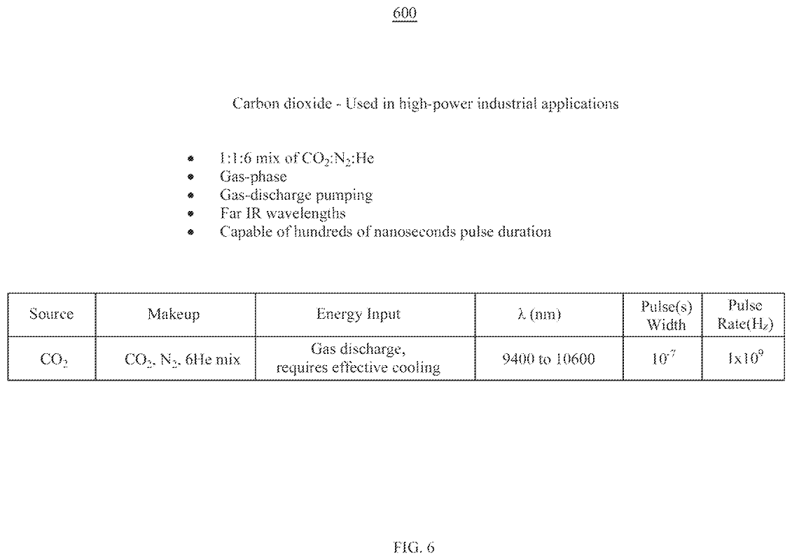

Commercially available lasers used for ablation of metals have focused on wavelengths in the range of 235 nm to 355 nm. FIG. 4 shows exemplary specifications for a commercially available neodymium-doped yttrium aluminum garnet (“Nd:YAG”) 3rd harmonics laser and FIG. 5 shows exemplary specifications for a commercially available titanium-sapphire (“Ti-sapphire”) laser that produce laser light within the range of 235 nm to 355 nm. While the primary frequency of Nd:YAG lasers, in the 964 nm to 1064 nm range may be used, to attain the best result with the least crystalline damage to the substrate, UV frequencies are favored. UV frequencies provide the best result across the widest range of types or kinds of semiconductors, metals, and oxides. In addition, a wide variety of power diode pumped solid state (“DPSS”) and fiber optic diode lasers are commercially available with sufficient power output at acceptable pulse rate frequencies, from 3 watts to 300 watts and 1 to 500 femtoseconds, for such use. While there are continuous wave gas source lasers, such as those based on helium-neon (He—Ne), argon (Ar), and carbon dioxide (CO₂), that produce the highest power per watt at the lowest cost, they produce excessive damage to the substrate and contaminate the substrate due to the melting and heating of the substrate by the light. In the case of mid-infrared lasers, such as CO₂ lasers in the 5 micron to 10.6 micron frequency range, these lasers are very difficult to focus and maintain the focus across the substrate surface and, worse yet, the semiconducting surfaces are invisible to these frequencies as soon as the ablated materials are removed due to heating and melting mechanisms. FIG. 6 shows exemplary specification for a commercially available CO₂ laser. Thus, there are commercially available lasers having wavelengths in the UV frequency range that may be used in accordance with one or more embodiments of the present invention.

In order to fully remove the structures or devices formed in or on the substrate, the light must maintain a depth of focus to the original substrate surface, which becomes a naturally reflective surface, in order for the ablation to cause damage approximately 5 to 10 microns into the substrate. In so doing, the impurities, as well as the structures formed in and on the substrate, are removed leaving the maximum amount of substrate to be reclaimed and polished for future use. In one or more embodiments of the present invention, it is believed that one of the most effective way to achieve this result is to use a Powell lens system. Whether scanning a circular gaussian or flat top laser wave-front manually in the x-, y-, or r-theta rastering motion by mechanical methods via carriage and stepping motors and belts or scanning by galvanometry via moving mirrors, either method can be used as long as the wave-front of light maintains focus on the top surface of the substrate and achieves the ionic ablation threshold.

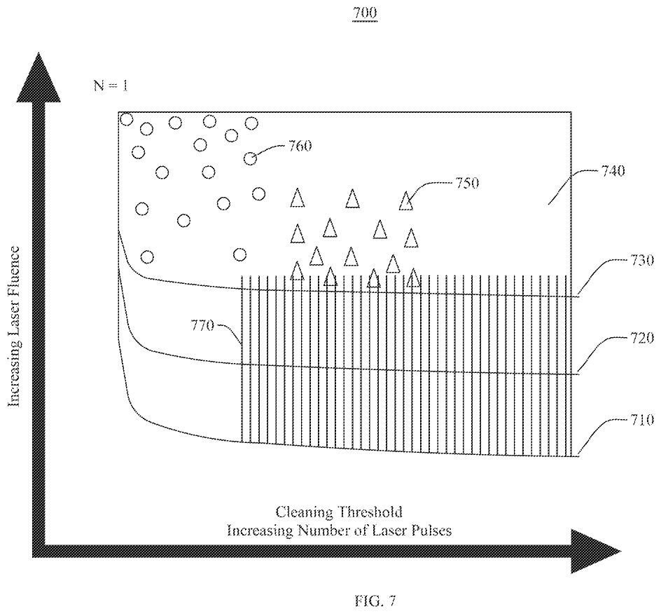

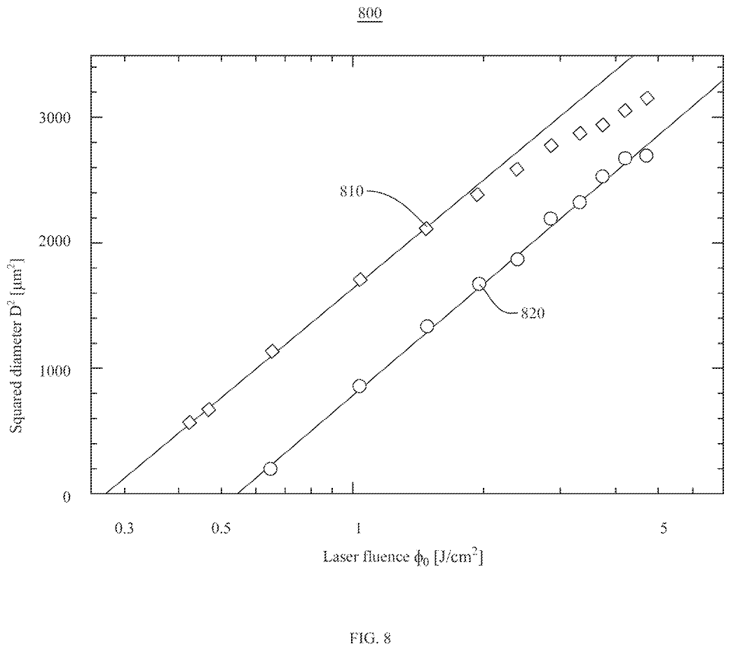

The reaction of polished semiconducting substrates to light of various wavelengths is well understood. The lowest wavelengths have the shallowest adsorption coefficient and are the most reflective to the laser light and therefore produce the least damage to the substrate counter to the ablation goal. A dramatic increase can be seen above wavelengths of approximately 380 nm, increasing steadily from tenths of microns to hundreds of microns above 1400 nm wavelength light. For example, it is well understood that the maximum reflectivity of polished silicon substrates occurs just below 300 nm, with light having a wavelength in the range between 275 nm to 280 nm. In order to reach the ablation threshold for a given metal such as, aluminum, cobalt, copper, gold, ruthenium, or tungsten, semiconductors such as, silicon, gallium-arsenide, indium-gallium-arsenide, silicon-carbide, indium-tin, and others, and dielectrics such as, silicon dioxide and silicon nitride, the laser must navigate four sequences of physical processes, namely, amorphization, melting, recrystallization, nucleated vaporization/boiling, and finally ablation. These physical processes of photo excitation of a solid to a vapor, creating a plume of highly accelerated ablated material may be achieved by crossing the ablation threshold fluence. FIG. 7 shows how increasing laser fluence achieves clean ablation without redeposition of material (slag) or melting. These physical processes of ionic photo excitation of a solid to vapor, creating a plume of highly accelerated ablated material, are achieved by increasing the laser fluence past the modification threshold 710 to enter the amorphization phase, past the crystallization threshold 720 to enter the annealing phase, and past the ablation threshold 730 to enter the clean ablation phase 740. For a given single 130 femtosecond pulse of a Ti-sapphire laser at 780 nm into silicon, the ablation threshold may be achieved at approximately 0.4 Joules/cm² as shown in FIG. 8, where 810 represents surface modification and 820 represents recrystallization. Multiple pulses of this laser demonstrate the different mechanisms in silicon as columns 750, bubbles 760, and ripples 770 emerge prior to complete clean vaporization or ablation. As such, depending on the excitation energy, short wavelength, frequency, and number of pulses of the light wave, thermal heating results in melting and undesirable columns, bubbles, ripples, and recrystallization due to inadequate exit velocities and thermal heating. In one or more embodiments, thermal heating is preferably avoided, giving rise to clean ablation of the material formed in and on the substrate surface directly into the vapor phase and a plume of material exits the surface, which can then be exhausted or vacuumed away from the now clean and minimally damaged surface of the substrate. Thus, the light must be selected and controlled in a manner that goes straight to the vapor phase for the clean ablation of the structures without causing significant damage to the substrate.

Pure metals tend to follow the two-temperature model (“TTM”) of diffusion, because the requisite energy required to excite pure metal beyond its melting point to the vapor phase is much easier due to the relatively low melting/vaporization point of pure metals. Electron drift or electromigration can cause the metal to tear apart physically as the applied energy exceeds the number of electrons available in the metal lattice. Semiconducting metals adsorb the light and must broach the ‘band gap’ or energy excitation level of the semiconductor substrate by photon excitation and then relaxation as photons of light are emitted as the semiconductor band gap is exceeded and the energy level relaxes. Electron-hole pairs propagate electrically during this process depending on dopant type (e.g., n-type/phosphorus-arsenic doped or p-type/boron doped in the case of silicon semiconductor substrate). These complex excitations and relaxation mechanisms follow a similar TTM diffusion equation model but have more complex second and third order mechanisms. Hence, the frequency of light should be kept shorter for semiconductor ablation, near the reflective maximum of 280 nm UV, and at sufficiently high power to reach the fluence minimum, with an optimized pulse width and repetition rate to attain a clean result minimizing heat effects below the heavy metal diffusion temperatures for the particular substrate. This is as compared to pure metals which are effectively ablated with minimal damage at the longer 1064 nm IR wavelengths. Dielectrics have higher melting points and vaporization points and larger bandgaps requiring higher photon energies, where multi-photon transitions are necessary to promote creation of free carriers across the wider band gaps. Ultimately, a semiconducting device is made of pure metals, intermetallic metal alloys/silicides, with barrier inter-metallics encapsulated by dielectrics sitting above and in combination with semiconducting metals. As such, it is very difficult to achieve a clean ablated surface, with minimal damage to the substrate, and with no remaining heavy metal diffusion contamination due to thermal heating of melted metals or redeposited metals by diffusion into the substrate.

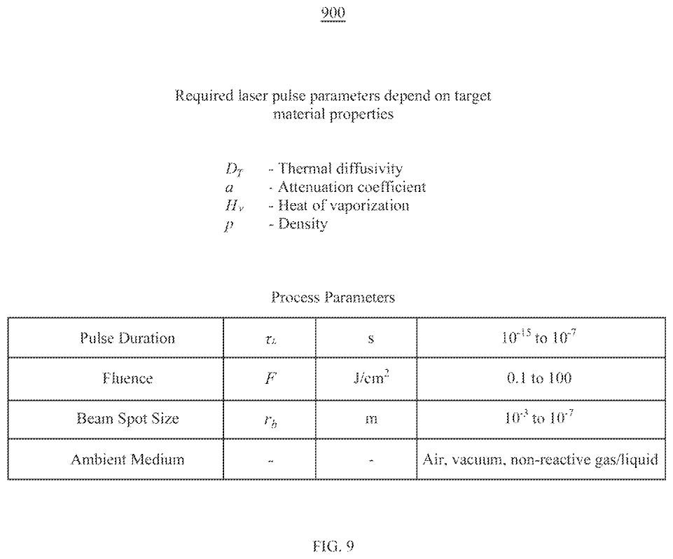

FIG. 9 shows ranges of laser pulse parameters in the TTM that are dependent on the material properties of the target substrate to be ablated in accordance with one or more embodiments of the present invention. As previously discussed, the pulse duration, τ_{L}, is typically measured in seconds and may be in a range between 10⁻¹⁵ and 10⁻⁷. The fluence, F, may be measured in Joules/cm² and may be a in a range between 0.1 and 100. The beam spot size, r_{b}, may be measured in meters and may be in a range between 10⁻³ (millimeters) to 10⁻⁷ (tenths of microns). The ambient medium through which the laser light pulse may pass to the targeted substrate will be air, vacuum, or non-reactive inert gas or liquid for the purpose of carrying the ablated vapors away from the wafer substrate, sufficiently minimizing contaminating redeposition. These mechanisms are understood by the accepted use of a TTM thermo-optical model. The laser-substrate material interaction with femtosecond pulses, where the pulse duration represented by, τ_{L}, is much shorter than the electron cooling time, represented by, τₑ. The mechanism described here follows the function of inverse Bremsstrahlung deceleration breaking radiation when a charged particle is deflected by another charged particle, typically an electron by an atomic nucleus. The laser beam energy will be adsorbed by free electrons from the material followed by thermalization (relaxing reaching thermal equilibrium) from within the electrons vibrating themselves.

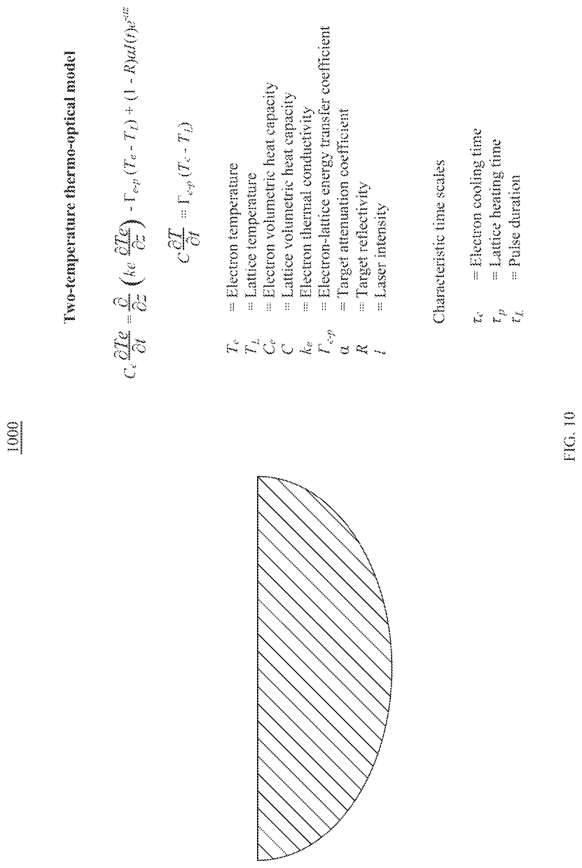

FIG. 10 shows a TTM thermo-optical model of laser ablation in relation to a wafer substrate in accordance with one or more embodiments of the present invention. The first differential equation in the TTM thermo-optical model is electron-photon coupling effect represented by:

$${C}_{e} \frac{\partial {T}_{e}}{\partial z} = \frac{\partial }{\partial z} ( k e \frac{\partial {T}_{e}}{\partial z} ) - {Γ}_{e - p} ( {T}_{e} - {T}_{L} ) + ( 1 - R ) aI ( t ) {e}^{- α z} \qquad ( 1 )$$

And the second equation is the lattice coupling heat effect represented by:

$$C \frac{\partial T}{\partial t} = {Γ}_{e - p} ( {T}_{e} - {T}_{L} ) \qquad ( 2 )$$

In the first equation the term Ce is the electron volumetric heat capacity of the solids being ablated, where Tₑ is the electron temperature differentiated over time, t, and volume, z. The term ke is the electron thermal conductivity. The electron thermal conductivity is multiplied by the differential over time and volume of the electron temperature, Tₑ, minus the electron-lattice energy transfer coefficient, Γₑ₋ₚ, multiplied by the difference in the electron temperature, Tₑ, minus the lattice temperature, T_{L}, plus the surface transmissivity, one minus the target reflectivity, R, multiplied by the target attenuation coefficient, a, multiplied by the laser intensity, I as a function of time, t, raised to the negative power of the target attenuation coefficient, a, multiplied by the volume, z. In the second TTM equation we see that the lattice volumetric heat capacity, C, of the target material differentiated over time is equal to the electron-lattice energy transfer coefficient multiplied by the difference in the electron temperature, Tₑ, and the lattice temperature, T_{L}.

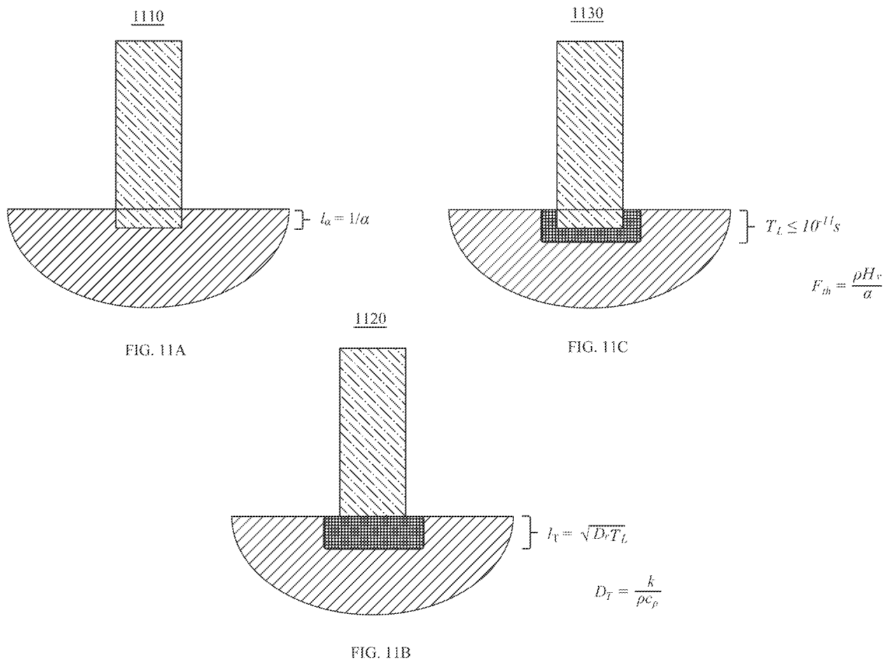

FIG. 11A shows the optical depth of adsorption of the intensity, l_{α}, of a laser or beam of light incident onto a substrate surface as a function of the target attenuation coefficient in accordance with one or more embodiments of the present invention. The laser intensity, l_{α}, as a function of the target attenuation coefficient, α, is equal to

$$\frac{1}{α} .$$

Continuing, FIG. 11B shows the thermal effect of a laser or beam of light incident/perpendicular onto a substrate as a function of the lattice temperature and penetration depth in accordance with one or more embodiments of the present invention. The thermal laser intensity, l_{T}, as a function of the thermal diffusivity, D_{T}, and pulse duration, τ_{L}, is equal to \sqrt{D_{T}τ_{L}}, where D_{T} is equal to

$$\frac{k}{ρ {C}_{ρ}} ,$$

and k is thermal conductivity, ρ is density, and C_{ρ} is substrate material density volumetric heat capacity. Continuing, FIG. 11C shows threshold fluence (point of ablation) in accordance with one or more embodiments of the present invention. The pulse width duration, τ_{L}, is approximately less than or equal to 10⁻¹² seconds for picosecond laser pulse width sources and 10⁻¹⁵ for femtosecond laser pulse width sources and the fluence threshold, Fₜₕ, is equal to

$$\frac{ρ {H}_{v}}{α} ,$$

and Hᵥ is the heat of vaporization of the material being ablated.

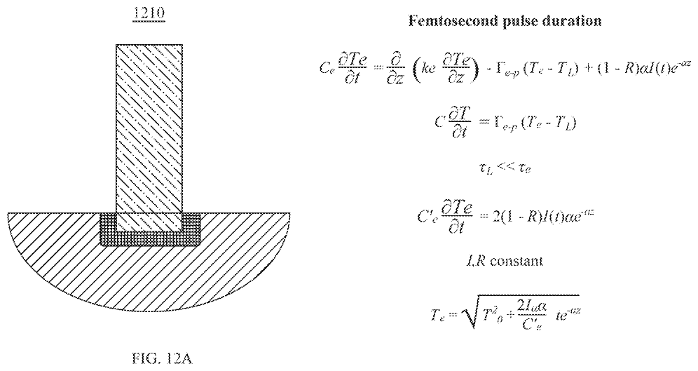

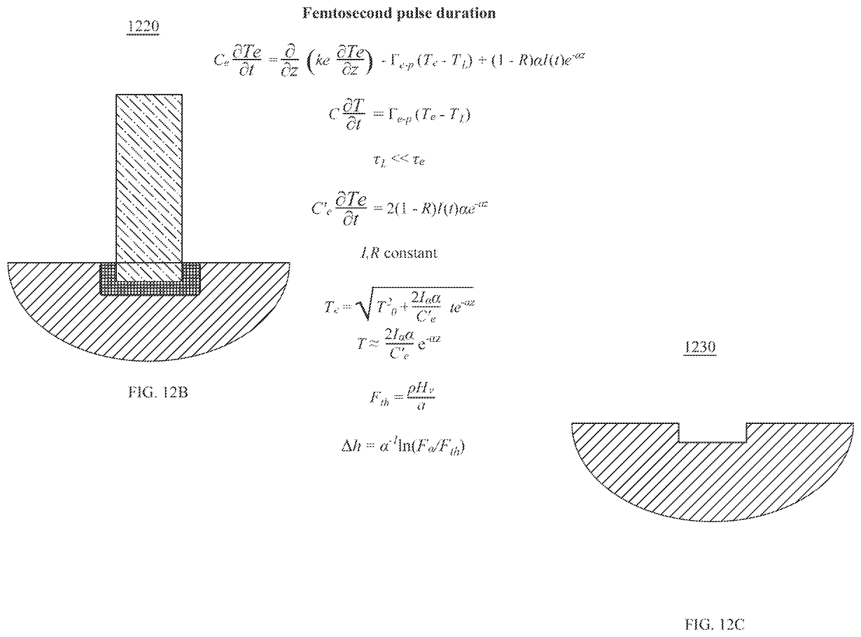

FIG. 12A shows a TTM thermo-optical model of a femtosecond pulsed laser into a wafer substrate in accordance with one or more embodiments of the present invention. The use of pulse width durations where the pulse duration is much shorter than the electron cooling time as in femtosecond sources yields the cleanest ablation due to the ionic light adsorption into the electrons causing fluence vaporization due to the pulse width duration, τ_{L}, being much less than the electron cooling time, τₑ, as represented by FIG. 12B, ending in a final ablation result as depicted in FIG. 12C for any given point of ablation based on constant laser intensity and a constant target reflectivity, R. Under these conditions the first ionic ablation equation can be reduced to:

$${C}_{e}^{′} \frac{\partial {T}_{e}}{\partial t} = 2 ( 1 - R ) a I ( t ) {e}^{- α z} \qquad ( 3 )$$

for Femtosecond laser conditions where pulse duration is much less than the electron cooling time represented by the assumption:

τ_{L}«τₑ (4)

as the electron temperature mechanism is dominated by:

$${T}_{e} = \sqrt{{T}_{0}^{2} + \frac{2 I {α}^{α}}{{C}_{e}^{′}} t {e}^{- α z}} \qquad ( 5 )$$

and where lattice temperature heating effect is neglected because of the femtosecond pulses where lattice cooling occurs after the ablation threshold is reached and can be approximated by:

$$T \approx \frac{2 I {α}^{α}}{{C}_{e}^{′}} {e}^{- α z} \qquad ( 6 )$$

Continuing, the amount of ablated material depth or height, Δh, becomes equal to the natural log of the ratio of the electron fluence F_{α} threshold divided by the threshold fluence of the lattice heating, Fₜₕ, (which is negated due to ionic electron dominance) multiplied by one over the target material attenuation coefficient, α, or by:

$$Δ h = {α}^{- 1} ln ( \frac{{F}_{α}}{{F}_{t h}} ) \qquad ( 7 )$$

Because significantly less heat is adsorbed during the ablation process in the femtosecond process regime, electrons are stripped from the materials atomic levels outer shells which result in higher escape velocities of vaporized materials and much less heat adsorbed damage into the substrate lattice. Cleaner ablation occurs which eliminates the negative effects of melting, slag, or redeposition of ablated materials seen in picosecond and slower laser pulses resulting in a lower chance of thermal diffusion of heavy metals into to the target substrate. The number of pulses and pulse frequency time as measured in Hertz frequency, Hz, and this determines the depth of direct ionic ablation. Milling or deep micromachining and cutting of the target substrate thereby removing excessive amounts of substrate is undesirable and is avoided by the movement of the laser across the substrate in meters per second in addition to the control of the number of pulses per unit area, centimeters squared, and the pulse frequency in time.

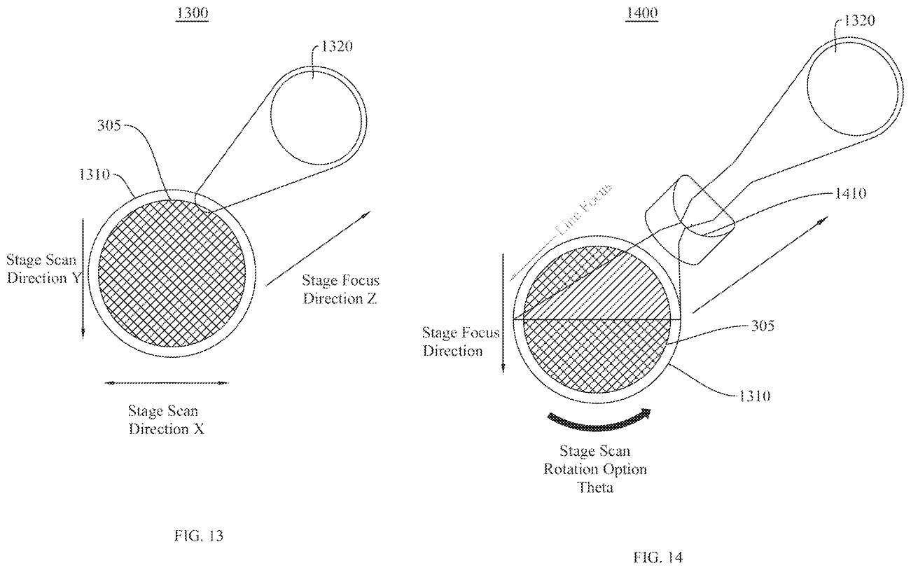

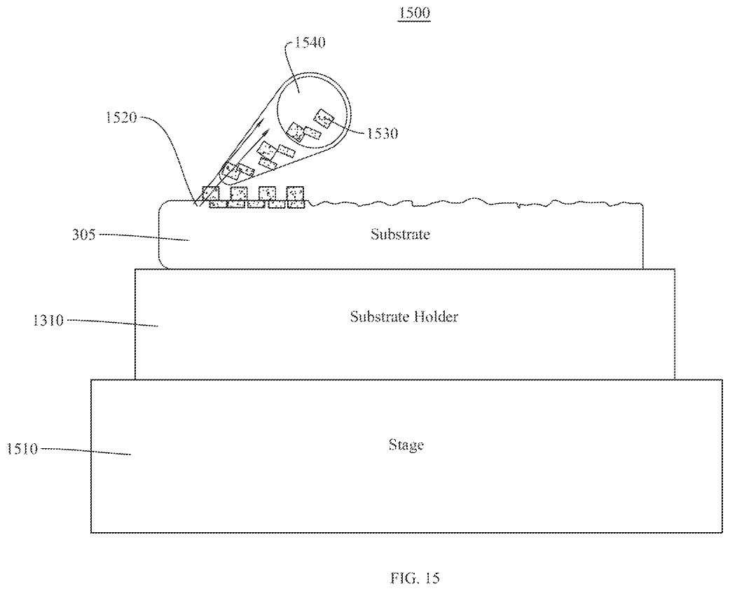

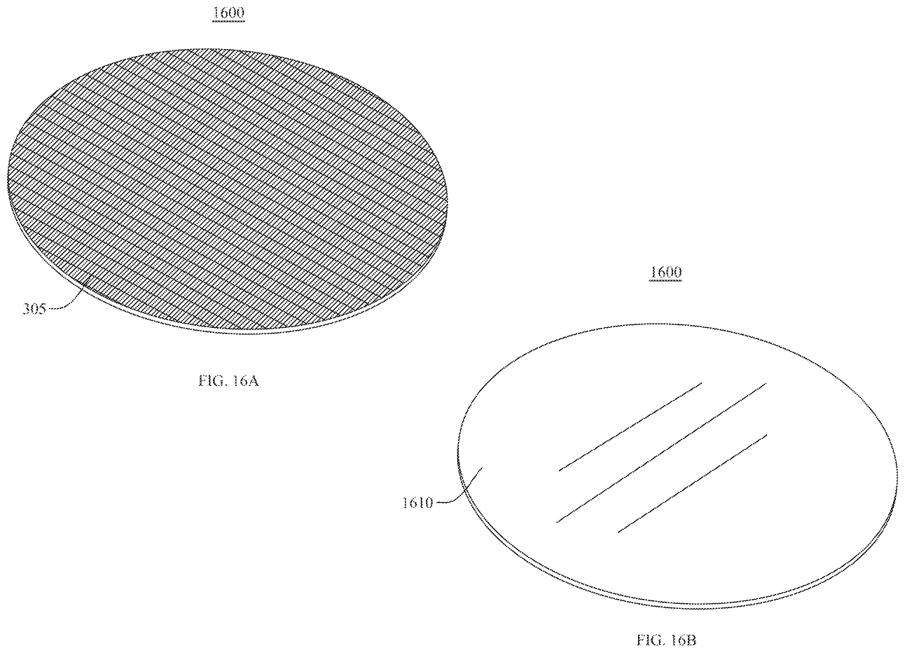

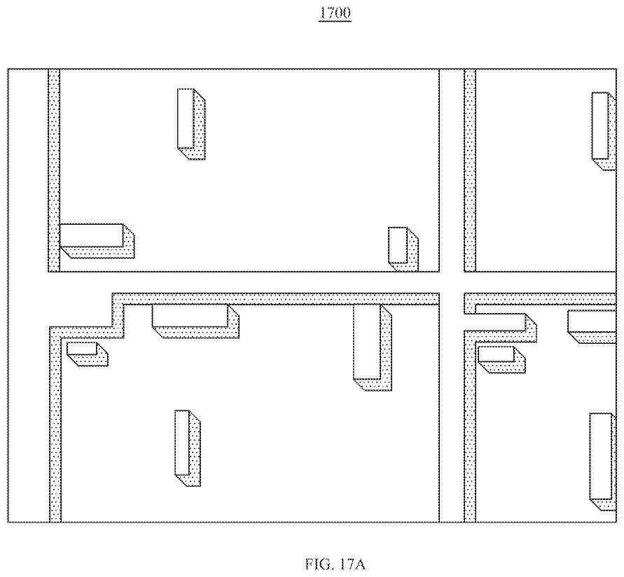

Scanning is accomplished by movement of a circular or ellipsoidal focused laser light spot pulse or a long wide line laser pulse mechanically as shown in FIG. 14 and FIG. 15 either by stage and or laser beam mechanical action in horizontal planes of x- and y-motions or rotational, theta r-, motions and patterns. These mechanical rastering overlapping scans in x- and y- or theta r-movements by movement of the substrate on a mechanical stage or by moving the last laser mirror or fiber optic or focusing lens mechanically by stepper motors or by galvanometric mirror scanning through a lens or by the use of a Powell lens optic to create a flat line of sufficient uniformity and intensity and laser pulse power to achieve the minimum ablation fluence threshold which reaches for each material to be removed must be processed under optimal motions for uniformity, speed and cost as well as to optimize and minimize surface roughness of the resulting substrate. Maintaining cleanliness of the ablated substrate either by inert gas or non-reactive gas purging, exhausting of the substrate surface by close proximity vacuuming at atmospheric pressure or if the ablation is done at sub-atmospheric conditions in a vacuum by continuous surface purging of those gasses to maintain large substrates free of redeposited solids. Additionally, the laser beam may be passed through a liquid medium of deionized water with very high resistivity or an inert liquid. In each case of the substrate processing at atmosphere under gas purging and vacuuming of ablated materials or under a sub-atmospheric vacuum or at atmosphere under a non-reactive pure liquid the resulting vapors and ablated solids of those vapors are to be captured by appropriate filtering medium for the purpose of separation and reclamation for reuse of these rare earth elements and for safety of the environment and of humans and animals. Substrate temperature itself must be maintained at low temperatures to maintain mechanical integrity and stability of the substrate as well as flatness and positional accuracy. This is the purpose of the substrate holder as depicted in FIG. 16 above the substrate staging system itself.

Picosecond and shorter nanosecond and lower laser pulses, while still following the TTM model, result in too much heat being adsorbed by the substrate lattice during ablation due to lower ablation escape velocities and a propensity to redeposition of vaporized materials (slag), melting (ripples, bubbles, or columns), which is undesirable surface build-up. In addition, the heat causes deep crystalline damage to the substrate due to thermal adsorption effects and will not be covered here. Even shorter laser pulses or continuous wave lasers in which ablation does occur results in damage and optical adsorption even further into the substrate due to the light wavelengths and thermal heating causing deep damage of the crystalline substrate and demonstrates micro thermo-explosions which drive unwanted heavy metal impurities into the substrate rendering it unrecoverable and mechanically weak therefore unpolishable and unable to be reclaimed for use as a test wafer or carrier wafer in the future.

FIG. 13 shows a circular or ellipsoidal (spot) laser impinging on a semiconductor wafer substrate in accordance with one or more embodiments of the present invention. A method of reclamation or recycling of a semiconductor workpiece may include disposing the substrate 305 on a substrate holder 1310. In preparation for treatment, the substrate 305 must be handled with care when placed in and removed from the substrate holder 1310 that must be kept clean and extremely flat. In order to maintain the cleanliness of the backside of the substrate 305, the substrate holder 1310 may be composed of pure quartz. Lifting pins or automatic robotic substrate handling may be used via blade vacuum handling. The substrate holder 1310 may be disposed on a substrate staging system (e.g., 1510 of FIG. 15) that facilitates staging the substrate 305. In certain embodiments, the substrate 305 may move to ensure one or more surfaces of the substrate 305 are exposed to the coherent light source 1320. The movement may be in the x- or y-axis direction and the staging system (e.g., 1510 of FIG. 15) may move in the z-axis direction to assist in focusing the coherent light source 1320. In other embodiments, such as that shown in FIG. 14, the substrate staging system (e.g., 1510 of FIG. 15) may be used to rotate the substrate. In such embodiments, a coherent light source 1320 may be directed through a Powell lens 1430 in order to form a line that, when used in combination with the staging system 1410 rotation of the substrate 305, ensures one or more surfaces of the substrate 305 are exposed to the coherent light source 1320, potentially faster than a spot laser application.

In certain embodiments, the substrate 305 may be disposed within a vacuum chamber (not independently illustrated) during exposure to coherent light and the method may include controlling the environment of the substrate 305 to a predetermined pressure. In some embodiments, the predetermined pressure may be in a range between 1 and 2 atmospheres. In other embodiments, the predetermined pressure may be in a range between 1 millitorr and 1 atmosphere. In still other embodiments, the predetermined pressure may be in a range between 10⁻⁷ torr and 1 millitorr. In certain embodiments, a gas purging system (not independently illustrated) may be used to purge the surface of the substrate 305 and an exhaust system (e.g., 1540 of FIG. 15) may be used to exhaust the surface of the substrate 305 during exposure. In vacuum chamber embodiments, the gas purging system may be used in combination with vacuum pumping and particle filtering in the post chamber exhaust process. In atmospheric embodiments, the gas purging system may be used in combination with any type or kind of exhaust system that exhausts the surface of the substrate 305.

A coherent light, generated by a coherent light source 1320, may be focused on a surface of the semiconductor substrate 305. In certain embodiments, the focal point of the coherent light may be adjusted by moving the substrate 305. In other embodiments, the focal point of the coherent light may be adjusted by moving the coherent light source 1320. In still other embodiments, the focal point may be directed at a predetermined depth objective, within the surface of the substrate 305. The predetermined depth objective may be a depth below the nominal substrate 305 surface, representing the extent of patterns, films, and materials, that must be removed to ensure removal of all the material formed in and on the substrate 305. In certain embodiments, the predetermined depth objective may be in a range between 5 microns and 30 microns.

The coherent light may have a predetermined wavelength, power, pulse width, pulse rate or number of pulses per unit area that causes direct ionic vaporization of material formed in or on the surface of the substrate 305 up to a predetermined penetration depth. In certain embodiments, the coherent light generated by the coherent light source 1320 may be directed through a lens (e.g., 1410 of FIG. 14), including potentially a Powell lens, or a mirror. In certain embodiments, the coherent light source 1320 may be an ultraviolet laser. In other embodiments, the coherent light source 1320 may be a visible light laser. In still other embodiments, the coherent light source 1320 may be an infrared laser. In still other embodiments, the coherent light source 1320 may be an excimer laser. In still other embodiments, the coherent light source 1320 may be an extreme ultraviolet source. In still other embodiments, the coherent light source 1320 may be a beam of light.

In certain embodiments, the predetermined wavelength may be in a range between 13.5 nanometers and 355 nanometers. In other embodiments, the predetermined wavelength may be in a range between 300 nanometers and 800 nanometers. In still embodiments, the predetermined wavelength may be in a range between 700 nanometers and 1.4 microns. In still embodiments, the predetermined wavelength may be in a range between 900 nanometers and 5 microns. In still embodiments, the predetermined wavelength may be in a range between 5 microns and 500 microns. In certain embodiments, the predetermined power may be in a range between 1 watt and 1,000 watts. In certain embodiments, the predetermined pulse width may be in a range between 10⁻⁶ seconds and 10⁻¹⁸ seconds. In certain embodiments, the predetermined pulse rate may be in a range between 1 Hertz and 50,000 Hertz. In certain embodiments, the predetermined penetration depth may be in a range between 1 micron and 30 microns. One of ordinary skill in the art, having the benefit of this disclosure, will appreciate that the selection of a coherent light source 1320 as well as guiding parameters may vary based on the target substrate 305, its composition, and the composition of the materials on the substrate 305.

In certain embodiments, the coherent light source 1320 may generate a coherent light that is focused on the surface of the substrate 305. As noted above, the substrate 305 either moves or rotates or the coherent light source 1320 moves to ensure that one or more surfaces of the substrate 305 are exposed to the coherent light. The gas purging system purges the surface of the substrate 305 while the exhaust system (e.g., 1540 of FIG. 15) exhausts the surface of the substrate 305, ensuring that there is no heavy metal contamination or redeposition during the process. Upon completion of the removal process, the substrate 305 may be inspected for compliance with roughness, final thickness, successful ablation specifications for one or more surfaces of the substrate 305. Subsequent to inspection, the substrate 305 may be polished, the polished substrate 305 may be inspected, and the polished and inspected substrate (e.g., 1610 of FIG. 16) may be returned to service as a test wafer or otherwise disposed with all intellectual property removed from the substrate 305.

In one or more embodiments of the present invention, warpage and breakage damage and the overall temperature of the substrate 305 may be controlled by maintaining substrate 305 surface temperatures below the crystal damage threshold of the particular substrate material and the diffusion threshold for impurities. Those skilled in the art of substrate temperature control in the manufacturing of semiconductor substrates are well versed in these bulk wafer temperature control methods by the use of static coupling, backside cooling, and/or in combination with a pocket for the accurate positioning of the substrate in the substrate holder as illustrated in FIGS. 13-15. The laser beam may be focused on the substrate 305 surface with femtosecond laser pulses and time compression bursts of laser light to maintain and optimize the direct ionic vaporization to the light beam focal point and allow the substrate 305 surface and dielectric, metal, and semiconducting layers to reach their ionic vaporization frequencies by stripping away the electrons from the materials outer electron shells instantaneously, converting them directly from a solid to gaseous state. Mid-infrared to far infrared wavelengths may also be utilized to create ablation of these materials, but substrate heating and deep damage can occur due to thermodynamic explosive reactions with the surface materials which can create deep pits, weaken the substrate, and drive impurities into the surface by thermo diffusion. These deep pits render the substrate unrecoverable and must be avoided to achieve a successful result.

In one or more embodiments of the present invention, the substrate temperature may be controlled during the process by backside cooling (e.g., static clamping, helium backside cooling) or immersion of the substrate in an inert liquid (e.g., deionized water) and surface cleanliness of the substrate may be controlled by purging the area immediately around the laser exposure area with a gas or an inert gas (e.g., argon, helium, or nitrogen) and vacuuming away the ablated materials. In certain embodiments, a knife edge purge with blow off gas that sweeps the ablated materials away from the substrate surface may be used. In a vacuum chamber, nozzle purge and flow dynamics must be controlled. A vacuum exhaust may be used to remove the ablated materials. In non-vacuum chamber embodiments, exhaust systems may be used to exhaust the surface of the substrate. Additionally, in-situ cleaning to avoid material redeposition may be achieved by vacuum cyclic nucleation (“VCN”) cleaning or sweeping the materials away in a soft flow of deionized water or solvent across the surface of the substrate simultaneously during the ablation process.

FIG. 14 shows a lined-based laser impinging on a wafer substrate in accordance with one or more embodiments of the present invention. In certain embodiments, the substrate staging system (e.g., 1510 of FIG. 15), may be used to rotate the substrate 305 such that the impinging line of coherent light is focused on the entire surface of the substrate. In such embodiments, the coherent light source 1320 may direct coherent light through a lens, such as, for example, a Powell lens 1410 to convert the spot beam to a line. As the substrate 305 rotates, the entire surface of the substrate may be exposed.

FIG. 15 shows a cross section of a system 1500 for reclamation or recycling of a semiconductor workpiece in accordance with one or more embodiments of the present invention. The system 1510 may include a substrate 305 disposed in a substrate holder 1310 that is disposed on a substrate staging system 1510 as previously discussed. The substrate staging system 1510 may move or rotate the substrate 305, the coherent light source (e.g., 1320 of FIG. 13 or 14) may move, or a combination of the substrate 305 and the coherent light source may move or rotate to ensure that one or more surfaces of the substrate 305 are exposed to the coherent light. A coherent light source (e.g., 1320 of FIG. 13 or 14) may generates a coherent light having a predetermined wavelength, power, pulse width, pulse rate or number of pulses per unit area that cause direct ionic vaporization of material formed in or on the surface of a semiconductor substrate 305 up to a predetermined penetration depth. A lens (e.g., 1410 of FIG. 14) or mirror may be used to focus the coherent light on the surface of the substrate 305. A gas purging system (not independently shown) may purge the surface of the substrate as the coherent light is focused on the substrate. An exhaust system 1540 may exhaust vapor and particulate matter 1530 as the coherent light source impinges 1520 the substrate 305.

In certain embodiments, the substrate 305 may be disposed within a vacuum chamber (not independently illustrated) during exposure to coherent light and the method may include controlling the environment of the substrate 305 to a predetermined pressure. In some embodiments, the predetermined pressure may be in a range between 1 and 2 atmospheres. In other embodiments, the predetermined pressure may be in a range between 1 millitorr and 1 atmosphere. In still other embodiments, the predetermined pressure may be in a range between 10⁻⁷ torr and 1 millitorr. In certain embodiments, a gas purging system (not independently illustrated) may be used to purge the surface of the substrate 305 and an exhaust system (e.g., 1540 of FIG. 15) may be used to exhaust the surface of the substrate 305 during exposure. In vacuum chamber embodiments, the gas purging system may be used in combination with vacuum pumping and wet particle filtering in the post chamber exhaust process. In atmospheric embodiments, the gas purging system may be used in combination with any type or kind of exhaust system that exhausts the surface of the substrate.

A coherent light, generated by a coherent light source 1320, may be focused on a surface of the semiconductor substrate 305. In certain embodiments, the focal point of the coherent light may be adjusted by moving the substrate 305. In other embodiments, the focal point of the coherent light may be adjusted by moving the coherent light source 1320. In still other embodiments, the focal point may be directed a predetermined ablation threshold, within the surface of the substrate 305. The predetermined ablation threshold may be a depth below the nominal substrate 305 surface, representing the extent of patterns, films, and material, that must be removed to ensure removal of all material formed in and on the substrate 305. In certain embodiments, the predetermined ablation threshold may be in a range between 5 microns and 30 microns.

The coherent light may have a predetermined wavelength, power, pulse width, pulse rate or number of pulses per unit area that causes direct ionic vaporization of material formed in or on the surface of the substrate 305 up to a predetermined penetration depth. In certain embodiments, the coherent light generated by the coherent light source 1320 may be directed through a lens (e.g., 1410 of FIG. 14), including potentially a Powell lens, or a mirror. In certain embodiments, the coherent light source 1320 may be an ultraviolet laser. In other embodiments, the coherent light source 1320 may be a visible light laser. In still other embodiments, the coherent light source 1320 may be an infrared laser. In still other embodiments, the coherent light source 1320 may be an excimer laser. In still other embodiments, the coherent light source 1320 may be an extreme ultraviolet source. In still other embodiments, the coherent light source 1320 may be a beam of light.

In certain embodiments, the predetermined wavelength may be in a range between 13.5 nanometers and 355 nanometers. In other embodiments, the predetermined wavelength may be in a range between 300 nanometers and 800 nanometers. In still embodiments, the predetermined wavelength may be in a range between 700 nanometers and 1.4 microns. In still embodiments, the predetermined wavelength may be in a range between 900 nanometers and 5 microns. In still embodiments, the predetermined wavelength may be in a range between 5 microns and 500 microns. In certain embodiments, the predetermined power may be in a range between 1 watt and 1,000 watts. In certain embodiments, the predetermined pulse width may be in a range between 10⁻⁶ seconds and 10¹⁸ seconds. In certain embodiments, the predetermined pulse rate may be in a range between 1 Hertz and 50,000 Hertz. In certain embodiments, the predetermined penetration depth may be in a range between 1 micron and 30 microns. One of ordinary skill in the art, having the benefit of this disclosure, will appreciate that the selection of a coherent light source 1320 as well as guiding parameters may vary based on the target substrate 305, its composition, and the composition of the materials on the substrate 305. For example, in certain embodiments using silicon substrates, the use of a 280-nanometer wavelength 300-watt laser light with femtosecond pulse rate has proven effective in cleanly vaporization material formed in or on the substrate up to the predetermined penetration depth.

In certain embodiments, the coherent light source 1320 may generate a coherent light that is focused on the surface of the substrate 305. As noted above, the substrate 305 either moves or rotates or the coherent light source 1320 moves to ensure that one or more surfaces of the substrate 305 are exposed to the coherent light. The gas purging system purges the surface of the substrate 305 while the exhaust system (e.g., 1540 of FIG. 15) exhausts the surface of the substrate 305, ensuring that there is no heavy metal contamination or redeposition during the process. Upon completion of the removal process, the substrate 305 may be inspected for compliance with roughness, final thickness, successful ablation specifications for one or more surfaces of the substrate 305. Subsequent to inspection, the substrate 305 may be polished, the polished substrate 305 may be inspected, and the polished and inspected substrate (e.g., 1610 of FIG. 16) may be returned to surface as a test wafer or otherwise disposed with all intellectual property removed from the substrate 305.

FIG. 16A shows a top-facing perspective view of a patterned wafer substrate 305 prior to ablation in accordance with one or more embodiments of the present invention. Continuing, FIG. 16B shows a top-facing perspective view of a post-processed wafer substrate 1610 after ablation in accordance with one or more embodiments of the present invention. The method of, and system for, reclamation or recycling of semiconductor workpieces effectively removed all structures or devices formed in or on the substrate, which is now ready for reclamation or safe recycling without risk of the unintended disclosure of intellectual property.

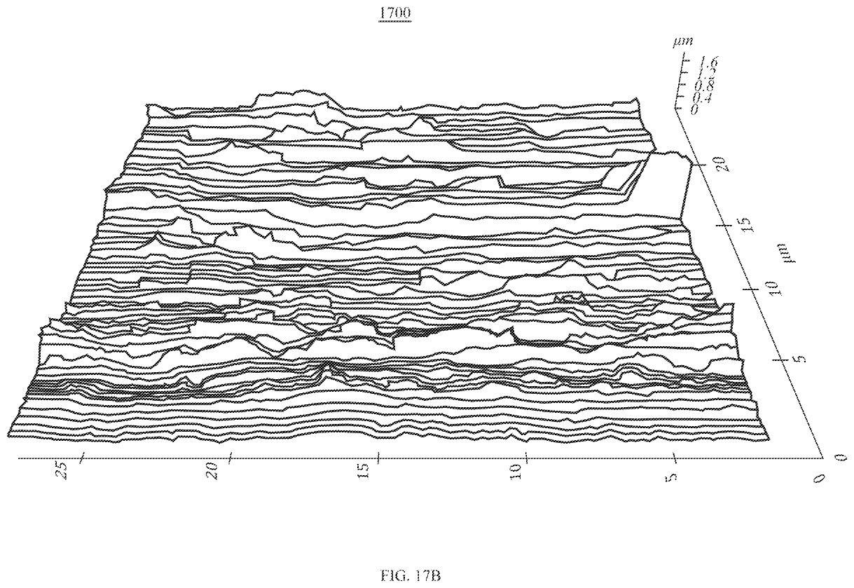

FIG. 17A shows a top plan perspective of an exemplary microscopic view 1700 of three-dimensional features, structures, or devices on a patterned wafer substrate in accordance with one or more embodiments of the present invention. For purposes of comparison, continuing, FIG. 17B shows an exemplary atomic force microscopy view 1700 of a formerly patterned wafer substrate surface after ablation in accordance with one or more embodiments of the present invention.

Advantages of one or more embodiments of the present invention may include one or more of the following:

In one or more embodiments of the present invention, a method of, and system for, reclamation or recycling of semiconductor workpieces enables the reuse or recycling of substantially full-thickness patterned wafers by a safe, non-hazardous, and green process for the complete removal of patterns from the substrate in a manner that leaves the base substrate of sufficient thickness and purity so that it may be polished back into a mirror-like finish for reuse as a test wafer or sold off as a carrier wafer, without risk of the unintended disclosure of intellectual property.

In one or more embodiments of the present invention, a method of, and system for, reclamation or recycling of semiconductor workpieces uses direct and instantaneous ionic vaporization to completely remove structures and material deposited, implanted, or formed in or on the substrate with minimal damage to the crystalline substrate. The purity of the substrate that meets heavy metal surface contamination specifications and has sufficient surface roughness that it may be polished back into a mirror-like finish using well known polishing or lapping processes.

In one or more embodiments of the present invention, a method of, and system for, reclamation or recycling of semiconductor workpieces enables the removal of a fab, foundry, or their client's intellectual property from a surface of a substrate with a high degree of confidence, without the use of harsh acids or chemicals, in a safe, economical, and environmentally conscious manner. Regardless of the intent to reclaim or merely recycle a wafer, the intellectual property may be cleanly vaporized from the surface of the substrate.

In one or more embodiments of the present invention, a method of, and system for, reclamation or recycling of semiconductor workpieces allows out of specification wafers, test wafers, and patterned wafers to be reclaimed for reuse as test wafers, meeting not only the outsize demand for test wafers, but also driving down costs.

In one or more embodiments of the present invention, a method of, and system for, reclamation or recycling of semiconductor workpieces allows out of specification wafers, test wafers, and patterned wafers to be recycled with a high degree of confidence that all intellectual property has been removed from the surface of the substrate.

In one or more embodiments of the present invention, a method of, and system for, reclamation or recycling of semiconductor workpieces enables, for the first time in the semiconductor industry, a process to reclaim or recycle patterned wafers in a safe, effective, and green manner with a high degree of confidence that intellectual property is fully removed from the substrate.

In one or more embodiments of the present invention, a method of, and system for, reclamation or recycling of semiconductor workpieces goes directly to instantaneous ionic vaporization to reduce or eliminate thermal action including melting, the formation of columns, bubbles, or ripples, recrystallization, and heavy metal contamination.

In one or more embodiments of the present invention, a method of, and system for, reclamation or recycling of semiconductor workpieces enables the removal of blanket films that are difficult to remove using mechanical grinding or polishing and wet or dry etching processes.

In one or more embodiments of the present invention, a method of, and system for, reclamation or recycling of semiconductor workpieces does not require the use of harsh acid chemicals to remove patterned structures or devices from the substrate.

In one or more embodiments of the present invention, a method of, and system for, reclamation or recycling of semiconductor workpieces focuses a coherent light source, having a predetermined wavelength, on a surface of a substrate at a predetermined power, pulse width, and pulse rate or number of pulses per unit area that causes direct and instantaneous ionic vaporization of material formed in or on the surface of the substrate without thermal damage or contamination to the substrate up to a predetermined penetration depth.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should only be limited by the appended claims.

What is claimed is:

1. A method of completely removing structures or materials deposited, implanted, or formed in or on a surface of a semiconductor substrate without chemicals comprising:
focusing coherent light on the surface of the substrate, wherein the coherent light has a predetermined wavelength, power, pulse width, and pulse rate or number of pulses per unit area that causes direct ionic vaporization of metals, dielectrics, and semiconducting materials deposited, implanted, or formed in or on the surface of the substrate up to a predetermined penetration depth with minimally acceptable damage to the crystalline substrate;
purging the surface of the substrate with an inert purge gas or liquid; and
exhausting the surface of the substrate,
wherein the substrate is free from heavy metal surface contamination and has a surface roughness capable of being polished back to a mirror-like finish.

2. The method of claim 1, further comprising:
disposing the substrate on a substrate holder;
disposing the substrate holder on a substrate staging system; and
controlling an environment of the substrate to a predetermined pressure.

3. The method of claim 1, further comprising:
directing the coherent light through a moveable lens or mirror.

4. The method of claim 1, further comprising:
moving the substrate to ensure one or more surfaces of the substrate are exposed to the coherent light.

5. The method of claim 1, further comprising:
rotating the substrate to ensure one or more surfaces of the substrate are exposed to the coherent light.

6. The method of claim 1, further comprising:
moving a coherent light source or a mirror to ensure one or more surfaces of the substrate are exposed to the coherent light.

7. The method of claim 1, further comprising:
inspecting a surface roughness of one or more surfaces of the substrate for compliance.

8. The method of claim 1, further comprising:
inspecting a final thickness of the substrate for compliance.

9. The method of claim 1, further comprising:
inspecting the ionic vaporized surface of the substrate for compliance.

10. The method of claim 1, wherein the substrate is disposed within a vacuum chamber.

11. The method of claim 1, wherein a focal point is adjusted by moving the substrate or moving a coherent light source.

12. The method of claim 1, wherein a focal point is directed at a predetermined location on or within the surface of the substrate.

13. The method of claim 2, wherein the predetermined pressure is in a range between 1 and 2 atmospheres.

14. The method of claim 2, wherein the predetermined pressure is in a range between 1 millitorr and 1 atmosphere.

15. The method of claim 2, wherein the predetermined pressure is in a range between 10⁻⁷ torr and 1 millitorr.

16. The method of claim 1, wherein the coherent light is generated by a coherent light source comprising an ultraviolet laser.

17. The method of claim 1, wherein the coherent light is generated by a coherent light source comprising a visible light laser.

18. The method of claim 1, wherein the coherent light is generated by a coherent light source comprising an infrared laser.

19. The method of claim 1, wherein the coherent light is generated by a coherent light source comprising an excimer laser.

20. The method of claim 1, wherein the coherent light is generated by a coherent light source comprising an extreme ultraviolet source.

21. The method of claim 1, wherein the coherent light is generated by a coherent light source comprising a beam of light.

22. The method of claim 1, wherein the predetermined wavelength is in a range between 13.5 and 355 nanometers.

23. The method of claim 1, wherein the predetermined wavelength is in a range between 300 and 800 nanometers.

24. The method of claim 1, wherein the predetermined wavelength is in a range between 700 nanometers and 1.4 microns.

25. The method of claim 1, wherein the predetermined wavelength is in a range between 900 nanometers and 5 microns.

26. The method of claim 1, wherein the predetermined power is in a range between 1 and 1,000 watts.

27. The method of claim 1, wherein the predetermined pulse width is in a range between 10⁻⁶ and 10⁻¹⁸ seconds.

28. The method of claim 1, wherein the predetermined pulse rate is in a range between 1 and 50,000 Hertz.

29. The method of claim 1, wherein the predetermined penetration depth is in a range between 1 and 30 microns.

30. A system for completely removing structures or materials deposited, implanted, or formed in or on a surface of a semiconductor substrate without chemicals comprising:
a coherent light source that generates a coherent light having a predetermined wavelength, power, pulse width, and pulse rate or number of pulses per unit area that causes direct ionic vaporization of metals, dielectrics, and semiconducting materials deposited, implanted, or formed in or on the surface of the substrate up to a predetermined penetration depth with minimally acceptable damage to the crystalline substrate;
a lens or mirror that focuses the coherent light on the surface of the substrate;
a gas purging system that purges the surface of the substrate; and
an exhaust system that exhausts the substrate.
